(19) United States
(12) Patent Application Publication
(10) Pub. No.: US 2015/0118802 A1
(43) Pub. Date: Apr. 30, 2015

(54) DUAL CORNER TOP GATE MOLDING

(71) Applicants: Boon Yew Low, Petaling Jaya (MY); Teck Beng Lau, Petaling Jaya (MY); Seng Kiong Teng, Shah Alam (MY); Shufeng Zhao, Beijing (CN)

(72) Inventors: Boon Yew Low, Petaling Jaya (MY); Teck Beng Lau, Petaling Jaya (MY); Seng Kiong Teng, Shah Alam (MY); Shufeng Zhao, Beijing (CN)

(73) Assignee: Freescale Semiconductor, Inc., Austin, TX (US)

(21) Appl. No.: 14/464,719

(22) Filed: Aug. 21, 2014

(30) Foreign Application Priority Data
Oct. 25, 2013 (CN) 201310511373.0

(51) Int. Cl. B29C 45/27; B29C 45/34; H01L 21/56; B29C 45/14

(52) U.S. Cl. CPC B29C 45/2708; B29C 45/14065; B29C 45/34; H01L 21/565; B29C 2045/14131; B29C 2045/2709
USPC 438/127; 425/500

(57) ABSTRACT

A mold die includes a side wall forming a hollow cavity and opposing first and second axial ends. The side wall has first and second openings respectively at the first and second axial ends. Each of the first and second openings accesses the hollow cavity. A main wall is coupled to the side wall at the first end thereof and spans the first opening. A center of the main wall is aligned with a longitudinal axis of the side wall. The main wall defines a plane oriented generally perpendicularly with respect to the longitudinal axis of the side wall. First and second gates are formed through the main wall to access the hollow cavity. The first and second gates define a first line lying in the plane of the main wall. The center of the main wall is located on the first line between the first and second gates.

### BACKGROUND OF THE INVENTION

The present invention is directed to a dual corner top gate molding for encapsulating a semiconductor chip and a method of encapsulating the semiconductor chip using the dual corner top gate molding.

Encapsulation of a semiconductor chip with a mold compound is a process requiring great care, particularly where the semiconductor chip is connected to the underlying substrate via wire bonds. The flow of the mold compound can cause wire sweep, i.e., lateral movement of the bond wires with respect to one another. Wire sweep can cause bond wires to become too close to one another, resulting in conduction interference or even a short where the bond wires come into physical contact.

So-called center gate molds alleviate many of the wire sweep issues. In center gate molds, the mold die is placed over the semiconductor chip, and includes a gate located in a top wall of the die and generally aligned with the center of the semiconductor chip. The mold compound is injected through the center gate and flows radially outwardly over the semiconductor chip. Air vents may be provided in the top wall of the die, generally spaced apart from the center gate, and may be aligned with corners of the semiconductor chip. This design of the mold also eliminates the need for gate runners, which are channels previously necessary to conduct the mold compound from the gate to the cavity within the mold die.

However, the center gate mold suffers from a “sieve effect.” That is, the wire bonds can act as a sieve on the mold compound as it flows over the sides of the semiconductor chip and through the wire bonds. Filler in the mold compound is retained and concentrated above the wire bonds, while below the wire bonds and under the edge of the semiconductor die the mold compound has a much lower concentration of filler and is therefore “resin rich.” The non-uniform dispersion of the filler in the mold compound poses a package reliability risk. For example, “resin rich” mold compound has a much higher coefficient of thermal expansion (CTE) than a homogenous mold compound. Delamination of the chip is also a possibility due to the uneven dispersion.

Attempts have been made to resolve the “sieve effect,” such as reduction of the size of the filler in the mold compound. However, size reduction has limitations, adds cost, and is a supplier-driven effect.

It is therefore desirable to provide a mold die that reduces the “sieve effect” while maintaining the advantages of center gate molds.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

In the drawings:

FIG. 1 is a top plan view of a mold die in accordance with a first embodiment of the invention;

FIG. 2 is a cross-sectional view taken through line 2-2 of the mold die of FIG. 1 in use to encapsulate a semiconductor chip;

FIG. 3 is a schematic perspective view of resin flow through the die mold of FIG. 1 to encapsulate a semiconductor chip; and

FIG. 4 is a cross-sectional view of a mold die in accordance with a second embodiment of the invention.

### DETAILED DESCRIPTION OF THE INVENTION

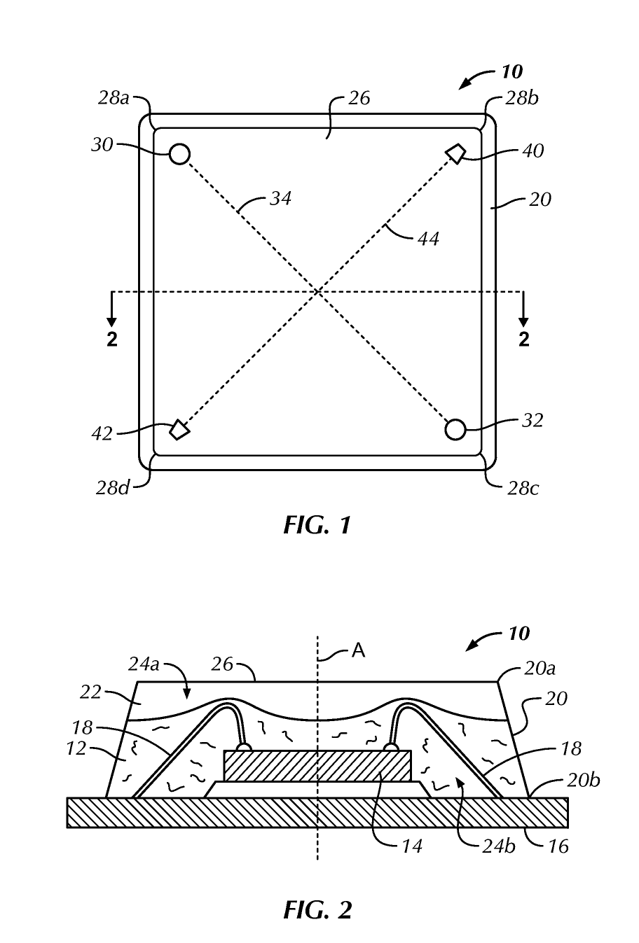

Referring to the drawings, wherein the same reference numerals are used to designate the same components throughout the several figures, there is shown in FIGS. 1 and 2 a mold die 10 in accordance with a first embodiment of the invention. The mold die 10 is used to apply a molding compound 12 to a semiconductor chip 14. The semiconductor chip 14 may be made from a conventional semiconductor material or combinations of materials, such as gallium arsenide, silicon germanium, silicon-on-insulator (SOI), silicon, monocrystalline silicon, the like, and combinations of the above, and may be connected to a substrate 16 via one or more bond wires 18. The device in use with the mold die 10 in FIGS. 1 and 2 is preferably a conventional tape ball grid array (TBGA) package. However, the mold die 10 may be used with other configurations (see e.g., FIG. 4).

The mold die 10 includes a side wall 20 forming a hollow cavity 22 to receive the semiconductor chip 14. The side wall 20 has first and second axial ends 20a, 20b arranged opposite to one another, and includes a first opening 24a at the first axial end 20a and a second opening 24b at the second axial end 20b. Each of the first and second openings 24a, 24b accesses the hollow cavity 22. Preferably, the semiconductor chip 14 is received in the hollow cavity 22 through the second opening 24b. It is also preferred that, in use, the second axial end 20b of the side wall 20 rests on a main surface of the substrate 16, although it is contemplated that the second axial end 20b of the side wall 20 may alternatively rest on other surfaces to receive the semiconductor chip 14 and/or may receive at least a portion of the substrate as well.

It is preferred that the side wall 20 is angled with respect to a longitudinal axis A extending between the first and second axial ends 20a, 20b such that the second opening 24b is larger than the first opening 24a. However, the side wall 20 may also extend parallel with the longitudinal axis A such that the first and second openings 24a, 24b are equally sized, or angled such that the first opening 24a is larger than the second opening 24b.

The side wall 20 is also preferably continuous around its perimeter, i.e., there are no openings or breaks in the side wall 20 other than the first and second openings 24a, 24b at the first and second axial ends 20a, 20b. However, it is contemplated that the side wall 20 may include additional openings formed therein as necessary for tool placement, venting, or the like.

It is preferred that the side wall 20, when viewed from one of the first or second axial ends 20a, 20b at any portion along the longitudinal axis A, generally has the form of a square or rectangle. In this form, the side wall 20 will have at least four distinct sides, which may all be formed from a single piece of material, or may be separate pieces that are welded or otherwise attached to one another to form the completed side wall 20. However, other shapes may also be formed by the side wall 20 for completing the desired shape of the finished semiconductor chip package (not shown).

The mold die 10 further includes a main wall 26 that is coupled to the side wall 20 at the first axial end 20a thereof. The main wall 26 spans the first opening 24a, thereby closing off the first axial end 20a of the side wall 20 with the exceptions described in further detail below. A center of the main wall 26 is preferably aligned with the longitudinal axis A, and the main wall 26 defines a plane oriented generally perpendicularly with respect to the longitudinal axis A of the side wall 20.

The main wall 26 and side wall 20 may be formed of a single piece of material, such as by molding or the like, or the main wall 26 may be mechanically or chemically attached to the side wall 20 coupled by welding, gluing, fasteners, or the like.

It is preferred that the main wall 26 generally match the shape of the side wall 20 at the first axial end 20a, e.g., a square or rectangle in preferred embodiments. Thus, the main wall 26 may have four corners 28a-d. The four corners 28a-d are shown in FIG. 1 as being chamfered, but the four corners 28a-d may also form right angles, be rounded, or the like. Depending on the shape of the main wall 26, fewer or more corners 28 may be utilized.

First and second gates 30, 32 are formed through the main wall 26 to access the cavity 22. The gates 30, 32 may be formed, for example, as part of a molding process of the main wall 26, or may be subsequently cut or punched from the material of the main wall 26.

Unlike in the prior art, rather than being formed at the center of the main wall 26, the first and second gates 30, 32 are preferably formed off-center and diagonally opposite from one another. For example, the first and second gates 30, 32 preferably define a first line 34 lying in the plane of the main wall 26, and the center of the main wall 26 is located on the first line 34 between the first and second gates 30, 32.

It is preferred that the first and second gates 30, 32 are each spaced apart from the center of the main wall 26 by an equal distance, although varying distances may be used as well.

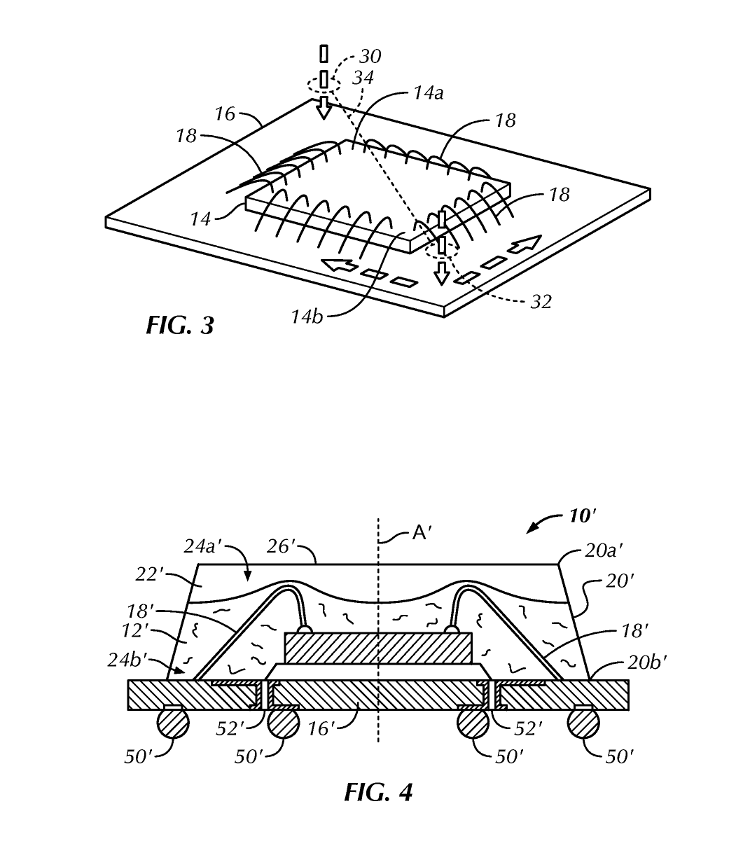

It is further preferred that the first and second gates 30, 32 are aligned with and may be formed proximate opposing corners 28 of the main wall 26. For example, as shown in FIG. 1, the first line 34 preferably intersects two corners 28a, 28c that are diagonally opposite from one another. The first gate 30 is preferably formed proximate the first corner 28a and the second gate 32 is preferably formed proximate the opposing corner 28c. However, the first and second gates 30, 32 may be formed closer to the center of the main wall 26 as necessary. Preferably, the main wall 26 is configured such that when the semiconductor chip 14 is received in the cavity 22, a first corner 14a and a second corner 14b of the semiconductor chip 14 are aligned with the first line 34 (see e.g., FIG. 3).

As shown in FIG. 3, the molding compound 12 can flow through the first and second gates 30, 32 and be dispersed below the bond wires 18, preventing the sieve effect. This is in contrast to the center gate design, where the molding compound is injected above the semiconductor chip and must flow radially outwardly to surround the edges and bond wires, which cause the sieving of the filler as the molding compound passes through the bond wires toward the bottom of the semiconductor chip. With the first and second gates 30, 32 of the present invention, the molding compound 12 enters near a corner 28a, 28c of the mold die 10, and can flow below and above the bond wires 18 without having to flow through.

Air vents 40, 42 are also preferably formed through the main wall 26 to access the cavity 22, thereby allowing the escape of air within the cavity 22 as the molding compound 12 is injected. It is preferred that, like the first and second gates 30, 32, the first and second vents 40, 42 are formed off-center and diagonally opposite to one another. For example, the first and second vents 40, 42 may define a second line 44 lying in the plane of the main wall 26, with the center of the main wall 26 being located on the second line 44 between the first and second vents 40, 42.

The second line 44 is preferably oriented perpendicularly with respect to the first line 34, which in some embodiments, such as the one shown in FIG. 1, will result in the vents being located proximate diagonally opposite corners 28b, 28d of the main wall 26 that are not associated with one of the first or second gates 30, 32. In particular, it is preferred that the second line 44 intersects two diagonally opposite corners 28b, 28d of the main wall 26.

In practice, the mold die 10 is placed on the substrate 16 such that the semiconductor chip 14 and the bond wires 18 are received in the cavity 22 through the second opening 24b, as shown, for example, in FIG. 2. This step may, as described above, include aligning diagonally opposite corners 14a, 14b of the semiconductor chip 14 with the first line 34. The molding compound 12 is then injected into the cavity 22 through both of the first and second gates 30, 32 and flows around the bond wires 18 to encapsulate the semiconductor chip 14 and the bond wires 18.

FIG. 4 shows, as an example of an alternative device for molding, a cross-section of a plastic ball grid array (PBGA) package in use with a mold die 10′ in accordance with the present invention. The PBGA package is much like the TBGA package shown in FIGS. 1 and 2, and so like elements have been designated with like reference numerals, although a prime (′) is used for the numerals in FIG. 4. The PBGA additionally includes a plurality of balls 50′, formed of solder or the like, on an underside of the substrate 16′. The solder balls 50′ are in communication with the wire bonds 18′ by vias 52′ formed in the substrate 16′.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A mold die for applying a molding compound to a semiconductor chip, the mold die comprising:
a side wall forming a hollow cavity to receive the semiconductor chip and having opposing first and second axial ends, the side wall having a first opening at the first axial end and a second opening at the second axial end, each of the first and second openings accessing the hollow cavity;
a main wall coupled to the side wall at the first axial end thereof and spanning the first opening, a center of the main wall being aligned with a longitudinal axis of the side wall, the main wall defining a plane oriented generally perpendicularly with respect to the longitudinal axis of the side wall; and
first and second gates formed through the main wall to access the hollow cavity, the first and second gates defining a first line lying in the plane of the main wall, the center of the main wall being located on the first line between the first and second gates.

2. The mold die of claim 1, further comprising first and second air vents formed through the main wall to access the hollow cavity, the first and second air vents forming a second line lying in the plane of the main wall, the center of the main wall being located on the second line between the first and second air vents.

3. The mold die of claim 2, wherein the second line is oriented perpendicularly with respect to the first line.

4. The mold die of claim 2, wherein the main wall includes four corners and the second line intersects two corners of the main wall diagonally opposite from one another.

5. The mold die of claim 1, wherein the main wall includes four corners, and the first line intersects two corners of the main wall diagonally opposite from one another.

6. The mold die of claim 5, wherein the four corners are one of right angles, rounded, or chamfered.

7. The mold die of claim 1, wherein the main wall is configured such that when the semiconductor chip is received in the cavity, a first corner of the semiconductor chip and a second corner of the semiconductor chip, are aligned with the first line, the first and second corners of the semiconductor chip being diagonally opposite from one another

8. The mold die of claim 1, wherein the second opening is larger than the first opening.

9. A method for encapsulating a semiconductor chip connected to a substrate with a plurality of bond wires, the method comprising:
providing a mold die having:
(i) a side wall forming a hollow cavity and having opposing first and second axial ends, the side wall having a first opening at the first axial end and a second opening at the second axial end, each of the first and second openings accessing the hollow cavity,
(ii) a main wall coupled to the side wall at the first end thereof and spanning the first opening, a center of the main wall being aligned with a longitudinal axis of the side wall, the main wall defining a plane oriented generally perpendicularly with respect to the longitudinal axis of the side wall, and
(iii) first and second gates formed through the main wall to access the hollow cavity, the first and second gates defining a first line lying in the plane of the main wall, the center of the main wall being located on the first line between the first and second gates;
placing the second axial end of the mold die on the substrate such that the semiconductor chip and the bond wires are received in the cavity of the mold die;
injecting a mold compound into the cavity through both of the first and second gates to encapsulate the semiconductor chip and the plurality of bond wires.

10. The method of claim 9, wherein the method further comprises providing, in the mold die, first and second air vents formed through the main wall to access the hollow cavity, the first and second air vents forming a second line lying in the plane of the main wall, the center of the main wall being located on the second line between the first and second air vents.

11. The method of claim 10, wherein the first and second air vents are provided such that the second line is oriented perpendicularly with respect to the first line.

12. The method of claim 11, wherein the main wall of the mold die includes four corners and the first and second air vents are provided such that the second line intersects two corners of the main wall of the mold die diagonally opposite from one another.

13. The method of claim 9, wherein the main wall of the mold die includes four corners, and the mold die is provided such that the first line intersects two corners of the main wall of the main die diagonally opposite from one another.

14. The method of claim 9, wherein the step of placing the mold die on the substrate includes aligning, along the first line, a first corner of the semiconductor chip and a second corner of the semiconductor chip, the first and second corners of the semiconductor chip being diagonally opposite from one another.
